(19) United States
(12) Patent Application Publication
(10) Pub. No.: US 2005/0098808 A1
(43) Pub. Date: May 12, 2005

(54) Electronic deivce and method for its fabrication

(76) Inventor: Bum-Ki Moon, Tokyo-to (JP)

Correspondence Address: FISH & RICHARDSON, PC, 12390 EL CAMINO REAL, SAN DIEGO, CA, 92130-2081, US

(21) Appl. No.: 10/704,034

(22) Filed: Nov. 7, 2003

(51) Int. Cl. H01L 29/76; H01L 21/00

(52) U.S. Cl. 257/295; 257/310; 257/306; 438/3; 438/244

(57) ABSTRACT

The present invention relates to a ferroelectric device comprising a ferroelectric capacitor and a method for its fabrication. The Qsw of the ferroelectric capacitor is improved by providing a rugged first electrode. The rugged first electrode causes a subsequently deposited ferroelectric layer to have a substantially hemispherical wavy surface thereby increasing the effective surface area between the ferroelectric layer and the electrodes.

### FIELD OF THE INVENTION

The present invention relates to a ferroelectric capacitor structure, more particularly a ferroelectric capacitor for an FeRAM device.

### BACKGROUND OF THE INVENTION

Ferroelectric devices utilise ferroelectric materials which can undergo spontaneous polarisation which remains when the applied field or voltage is removed. They therefore lend themselves to fabrication of non-volatile memory devices, for example ferroelectric random access memories (FRAMs). Typical ferroelectric materials usable for the fabrication of such devices are lead zirconium titanate (PZT), and strontium bismuth tantalate (SBT).

A conventional FeRAM capacitor 1 is shown in FIG. 1 of the accompanying drawings.

In this device 1, on an interlayer dielectric material 3, is formed a lower electrode layer 5, followed by a ferroelectric capacitor layer 7 and then a top electrode layer 9.

After isolation of the device region 11 by etch-back, the device is encapsulated with an encapsulation layer 13. Contact holes and address lines on the wafer are formed in the usual way.

The switching charge or polarisation (Q_{sw}) of the ferroelectric material in such a device is the charge available for memory as the polarity is changed. The Q_{sw} value can be degraded by elevated temperature, the presence of hydrogen and fatigue due to repeated changes of the applied voltage. It is therefore important for the intrinsic Q_{sw} value of a newly manufactured device to be as high as possible.

Hitherto, the only means available for improving Q_{sw} has been to endeavour to increase the quality of the ferroelectric layer. This is particularly so for the commonly used offset-cell structure whereby the ferroelectric capacitor is integrated into a circuitry by contacting the electrodes of the capacitor via conductive lines.

The present invention provides a method of increasing Q_{sw} without resorting to methods for increasing the intrinsic quality of the ferroelectric layer.

### DEFINITION OF THE INVENTION

The present invention increases the intrinsic Q_{sw} value of a ferroelectric device by increasing the effective capacitor area. Generally, the ferroelectric capacitor structure comprises a first electrode layer, a second electrode layer and a ferroelectric layer situated between the first and second electrode layers. The increase in effective capacitor area is effected by providing a rugged first electrode. The rugged first electrode causes the subsequently formed ferroelectric layer to have a substantially hemispherical wavy surface thereby increasing the effective surface area between the ferroelectric layer and the electrodes of the capacitor.

The present invention is advantageous as a larger intrinsic Q_{sw} value is achieved without having to increase capacitor dimensions or improve the quality of the ferroelectric layer.

A first aspect of the present invention increases the effective capacitor area by providing a ferroelectric capacitor structure formed on a textured layer. The textured layer causes a subsequently deposited first electrode of the ferroelectric capacitor to have a rugged surface. Preferably, the textured layer comprises textured poly-silicon such as hemispherical grain (HSG) poly-silicon or rugged poly-silicon.

In one embodiment, the textured poly-silicon layer is formed on a regular poly-silicon layer which is formed overlying an interlayer dielectric. To facilitate high-density integration, preferably, the regular poly-silicon layer is formed to be in contact with a poly-silicon plug situated within said interlayer dielectric.

Still further to increase surface area, the textured poly-silicon layer is formed on a poly-silicon island region situated above an interlayer dielectric. Preferably, and also to enhance high-density integration, the poly-silicon island region is formed in contact and above a poly-silicon plug formed within the interlayer dielectric.

In a second aspect of the present invention, a rugged first electrode layer may be also be formed by grid deposition. In one embodiment, grid deposition comprises sputtering an electrode material such as platinum (Pt) through a grid onto the surface of an electrode of the same material.

In an actual device, preferably the aforementioned kinds of structure are covered with an encapsulation layer of conventional type. In an actual memory, an array is provided on a single wafer of any such ferroelectric devices according to the present invention. That structure preferably contains contacts to each device and address lines formed in conventional manner.

Preferably, the ferroelectric material is PZT, SBT or BLT (Bi—La—Ti—O).

Devices according to the present invention may in general be formed by growth of the relevant layers by conventional CVD and/or PVD techniques. In particular, formation of the HSG layer may be effected by the method described in U.S. Pat. No. 6,465,301.

### BRIEF DESCRIPTION OF THE FIGURES

The present invention will now be explained in more detail by way of the following non-limiting description of preferred embodiments and with reference to the accompanying drawings in which:

FIG. 1 shows a cross-section through a conventional FeRAM capacitor device;

FIG. 2 shows a cross-section through a FeRAM capacitor device in accordance with one embodiment of the present invention;

FIG. 3 shows a cross-section through a FeRAM capacitor device in accordance with a second embodiment of the present invention; and

FIG. 4 shows a cross-section through a third embodiment of an FeRAM capacitor device according to the present invention.

### DETAILED DESCRIPTION OF THE INVENTION

In accordance with one aspect of the present invention, the rugged first electrode is effected by forming the ferroelectric capacitor on a textured layer. Preferably, the textured layer comprises textured poly-silicon such as hemispherical grain (HSG) poly-silicon or rugged poly-silicon.

In one embodiment of the present invention, the HSG poly-silicon or rugged poly-silicon may be deposited using conventional methods such as physical vapour deposition (PVD) or low pressure chemical vapour deposition (LPCVD).

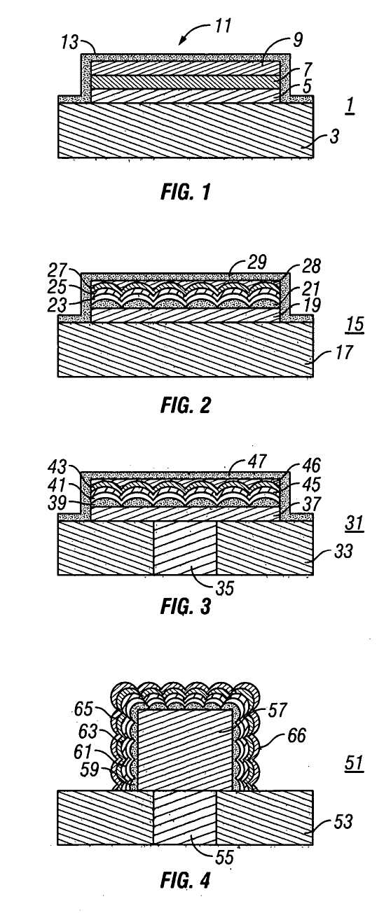

Alternatively, in one preferred embodiment of the present invention 15 shown in FIG. 2, a normal poly-silicon layer 19 is first formed on an interlayer dielectric film 17. A layer having a hemispherical grain structure 21 is then formed on the surface of the poly-silicon layer 19. In one embodiment, the layer having a hemispherical grain comprises HSG poly-silicon. The HSG layer may be formed by conventional methods such as annealing the normal poly-silicon layer under high temperature and high vacuum conditions or by using the method described in U.S. Pat. No. 6,465,301. Alternatively, in another embodiment, the hemispherical grain layer 21 formed on the normal poly-silicon layer 19 comprises rugged poly-silicon. The formation of the ferroelectric layer 21 is followed by formation in turn, of an insulating layer 23, first electrode layer 25, a ferroelectric capacitor layer 27 and a second electrode layer 28. These relevant layers may be formed by conventional methods such as PVD and/or CVD. Isolation of the device with formation of contacts and encapsulation with an upper layer 29 is effected in the same way as for the conventional device shown in FIG. 1.

Here, it is important to note that the hemispherical grain layer 21 causes formation of a greater surface area of the device defined by formation of the electrode layers 25, 28 and the ferroelectric capacitor layer 27 (preferably of PZT). The shape and effective surface area of the ferroelectric layer 25 formed can be controlled by the size and density of the grains in the HSG layer 21. In a preferred embodiment, the hemispherical grain layer 21 formed is large grain size HSG poly-silicon or rugged poly.

By using VLSI/ULSI techniques, it is possible to provide a higher density of integration by using a capacitor over plug structure wherein a ferroelectric capacitor in accordance with the present invention is formed over a conductive plug. FIG. 3 depicts one such embodiment. In this device 31, a poly-silicon plug 35 is formed in an interlayer dielectric film 33 by conventional masking, etching and deposition methods, followed by a regular poly-silicon layer 37 which rests on top of and in contact with, the interlayer dielectric layer 33 and the poly-silicon layer plug 35.

Then, in like manner to the device depicted in FIG. 2, are formed in turn, a HSG layer 39, an insulating layer 41, a lower or first electrode layer 43, a ferroelectric capacitor layer 45 and an upper or second electrode layer 46. Then, after isolation of the individual device on the wafer, encapsulation layer 47 and contacts (not shown) can be manufactured.

Finally, in order to embody both the advantage of increased surface area and therefore, improve Q_{sw} and also high-density integration, a device 51 comprised of a 3 dimensional stacked cell structure as shown in FIG. 4 can be fabricated according to the present invention. Here, an interlayer dielectric 53 has formed therein, a poly-silicon plug 55. Above the plug is deposited a region of poly-silicon denoted by numeral 57 which is situated directly above and in contact with the poly-silicon plug 55 whilst overlapping and in contact with part of the interlayer dielectric film 53. By suitable etching, this region 57 is isolated. Then, formed thereon, over the upper and side surfaces of the poly-silicon (or node) region 57, are formed in turn, a HSG film 59, an insulating layer 61, a first electrode layer 63, a ferroelectric PZT layer 65 and an upper electrode layer 66. The encapsulation layer is omitted from the drawing of FIG. 4.

In another aspect of the present invention, a rugged first electrode layer can also be provided by grid deposition. In one embodiment, grid deposition comprises sputtering an electrode material such as platinum (Pt) through a grid onto the surface of a first electrode of the same material. A ferroelectric layer and second electrode are then formed sequentially on the grid deposited first electrode layer to give a ferroelectric capacitor structure. The rugged first electrode layer provides a large surface area and causes the formation of a ferroelectric capacitor having an increased effective capacitor area.

In the light of the described embodiments, modifications of these embodiments, as well as other embodiments, within the spirit and scope of the present invention will now become apparent.

1. A ferroelectric capacitor structure comprising:
a rugged first electrode;
a textured layer, the textured layer causing the a ruggedness of the first electrode;
a second electrode;
a ferroelectric layer, deposited subsequently to the first electrode formed between the first and second electrodes; and
the rugged first electrode causing the subsequently deposited ferroelectric layer to have a substantially hemispherical wavy surface thereby increasing the effective area between the ferroelectric layer and the first and second electrodes.

2. (canceled)

3. The ferroelectric capacitor structure of claim 1, wherein the textured layer is a textured poly-silicon layer.

4. The ferroelectric capacitor structure of claim 3, wherein the textured poly-silicon layer is comprised of hemispherical grain poly-silicon.

5. The ferroelectric capacitor structure of claim 3, wherein the textured poly-silicon layer is comprised of rugged poly-silicon.

6. The ferroelectric capacitor structure of claim 3, wherein the textured poly-silicon layer is formed on a poly-silicon layer overlying an interlayer dielectric layer.

7. The ferroelectric capacitor structure of claim 6, wherein the interlayer dielectric layer has formed therein, a poly-silicon plug in contact with the poly-silicon layer.

8. The ferroelectric capacitor structure of claim 3, wherein the textured poly-silicon layer is formed on a poly-silicon island region above an interlayer dielectric layer.

9. The ferroelectric capacitor structure of claim 8, wherein a poly-silicon plug is formed within the interlayer dielectric layer and is in contact with the poly-silicon island region.

10. A semiconductor memory device comprising an array of ferroelectric capacitor structures according to claim 1.

11. (canceled)

12. (canceled)

13. A method of fabricating a ferroelectric capacitor structure, the method comprising:
forming a rugged first electrode;
forming a textured layer prior to forming the rugged first electrode, the textured layer causing a ruggedness of the first electrode;
forming a second electrode; and
forming a ferroelectric layer disposed between the rugged first electrode and the second electrode, the rugged first electrode causing the ferroelectric layer to have a substantially hemispherical wavy surface, thereby increasing the effective area between the ferroelectric layer and the first and second electrode.

14. (canceled)

15. The method of claim 13, wherein the textured layer is a textured poly-silicon layer.

16. The method of claim 15, wherein the textured poly-silicon layer comprises hemispherical grain poly-silicon.

17. The method of claim 15, wherein the textured poly-silicon layer comprises rugged poly-silicon.

18. The method of claim 13, wherein forming the rugged first electrode comprises depositing the rugged first electrode using grid deposition.

19. The ferroelectric capacitor structure of claim 18 wherein grid deposition comprises sputtering an electrode material through a grid onto the surface of an electrode of the same material.
